(19) United States
(12) Patent Application Publication
(10) Pub. No.: US 2021/0391557 A1
(43) Pub. Date: Dec. 16, 2021

(54) OLED DISPLAY DEVICE AND DISPLAY APPARATUS

(71) Applicant: Wuhan China Star Optoelectronics Semiconductor Display Technology Co., Ltd., Wuhan (CN)

(72) Inventor: Jing NI, Wuhan (CN)

(73) Assignee: Wuhan China Star Optoelectronics Semiconductor Display Technology Co., Ltd., Wuhan (CN)

(21) Appl. No.: 16/641,259

(22) PCT Filed: Dec. 20, 2019
(86) PCT No.: PCT/CN2019/126998

§ 371 Date: Feb. 24, 2020

(30) Foreign Application Priority Data
Oct. 25, 2019 (CN) 201911023118.5

(51) Int. Cl. H01L 51/52; H01L 27/32

(52) U.S. Cl. CPC H01L 51/5275; H01L 51/0097; H01L 51/5271; H01L 27/3246

(57) ABSTRACT

The present invention provides an organic light-emitting diode (OLED) display device. By adding a refraction-reflection layer into an encapsulation layer of the OLED display device, and by adjusting a refractive index of the refraction-reflection layer and a refractive index of the encapsulation layer, the refraction-reflection layer can change a path of light emitted to the surroundings, and light emitted from a light-emitting layer of the OLED display device is refracted or reflected by the refraction-reflection layer. Therefore, the light is emitted concentratedly from the center, and light-emitting efficiency from a front side of the OLED display device is improved.

### 1. FIELD OF DISCLOSURE

The present invention relates to a field of display technology and in particular, to an organic light-emitting diode (OLED) display device and a display apparatus.

### 2. DESCRIPTION OF RELATED ART

Compared with conventional liquid crystal display devices, OLED (organic light-emitting diode) display devices are thinner and lighter, and they have advantages such as being self-luminous, low power consumption, no backlight, no viewing angle limitation, and fast response speed.

OLED display devices in conventional OLED display apparatuses are categorized into two different structures: a bottom emission structure and a top emission structure. Taking the top emission structure as an example, the OLED display device includes a plurality of pixels arranged in an array, and each pixel includes an anode, a light-emitting layer, and a cathode sequentially formed on a substrate. When a voltage is applied between the anode and the cathode, holes are transferred from the anode to the light-emitting layer, the holes are combined with electrons transferred from the cathode to excite a light-emitting material in the light-emitting layer and generate light, and the light is emitted from the cathode to achieve top emission.

The light-emitting layer in the pixel emits light to all around, wherein besides the light emitted to the anode, some of the light is emitted out from a lateral side of the light-emitting layer. Consequently, a proportion (i.e., a light output ratio of the OLED display device) of light (i.e., light emitted from the cathodes of the pixels) emitted from a surface of the OLED display device in the light generated by all of the light-emitting layers of the pixels is low, thus leading to a large color shift of the display device and compromising the display quality.

### SUMMARY

A conventional organic light-emitting diode (OLED) display device has a low light output ratio and a large color shift. In order to solve the above problems, the present application provides an OLED display device and a display apparatus.

In one aspect, the present application provides an OLED display device. The OLED display device comprises a light-emitting layer, an encapsulation layer, and a refraction-reflection layer disposed in the encapsulation layer, wherein the refraction-reflection layer is configured to refract or reflect light of the light-emitting layer, so that the light is emitted concentratedly.

The encapsulation layer comprises a first inorganic layer, a second inorganic layer, and an organic layer disposed between the first inorganic layer and the second inorganic layer; the first inorganic layer is disposed on the light-emitting layer, the refraction-reflection layer is disposed on the organic layer, and the second inorganic layer is disposed on the refraction-reflection layer.

According to one embodiment, a refractive index of the refraction-reflection layer is greater than a refractive index of the organic layer.

According to one embodiment, a refractive index of the second inorganic layer is greater than or equal to a refractive index of the refraction-reflection layer.

According to one embodiment, the refraction-reflection layer comprises a plurality of refraction-reflection portions, and the refraction-reflection portions are spaced apart from each other.

According to one embodiment, a plurality of arc-shaped grooves are defined in one side of the organic layer away from the first inorganic layer, the refraction-reflection portions are correspondingly disposed in the arc-shaped grooves, and a cross-section of each refraction-reflection portion is oval or circular.

According to one embodiment, the OLED display device further comprises a flexible substrate, a thin film transistor (TFT) layer disposed on the flexible substrate, and a pixel definition layer disposed on the TFT layer; the pixel definition layer comprises a plurality of pixels spaced apart from each other, and a width of the refraction-reflection portion is less than or equal to an opening distance between each two adjacent pixels.

According to one embodiment, the refraction-reflection portion is disposed above an opening between each two adjacent pixels.

According to one embodiment, a light transmittance of the refraction-reflection layer is greater than 90%.

According to one embodiment, the refraction-reflection layer and the organic layer are made of a same material.

In another aspect, the present application provides a display apparatus. The display apparatus comprises an organic light-emitting diode (OLED) display device. The OLED display device comprises a light-emitting layer, an encapsulation layer, and a refraction-reflection layer disposed in the encapsulation layer, and the refraction-reflection layer is used to refract or reflect light of the light-emitting layer, so that the light is emitted concentratedly.

According to one embodiment, the encapsulation layer comprises a first inorganic layer, a second inorganic layer, and an organic layer disposed between the first inorganic layer and the second inorganic layer, the first inorganic layer is disposed on the light-emitting layer, the refraction-reflection layer is disposed on the organic layer, and the second inorganic layer is disposed on the refraction-reflection layer.

According to one embodiment, a refractive index of the refraction-reflection layer is greater than a refractive index of the organic layer.

According to one embodiment, a refractive index of the second inorganic layer is greater than or equal to a refractive index of the refraction-reflection layer.

According to one embodiment, the refraction-reflection layer comprises a plurality of refraction-reflection portions, and the refraction-reflection portions are spaced apart from each other.

According to one embodiment, a plurality of arc-shaped grooves are defined in one side of the organic layer away from the first inorganic layer, the refraction-reflection portions are correspondingly disposed in the arc-shaped grooves, and a cross-section of each refraction-reflection portion is oval or circular.

According to one embodiment, the OLED display device further includes a flexible substrate, a thin film transistor (TFT) layer disposed on the flexible substrate, and a pixel definition layer disposed on the TFT layer; the pixel definition layer comprises a plurality of pixels spaced apart from each other, and a width of the refraction-reflection portion is less than or equal to an opening distance between each two adjacent pixels.

According to one embodiment, the refraction-reflection portion is disposed above an opening between each two adjacent pixels.

According to one embodiment, a light transmittance of the refraction-reflection layer is greater than 90%.

According to one embodiment, the refraction-reflection layer and the organic layer are made of a same material.

Advantages of the present invention are as follows:

By adding a refraction-reflection layer into an encapsulation layer of the OLED display device, the refraction-reflection layer can change a path of light emitted to the surroundings, so that the light emitted from the light-emitting layer of the OLED display device is refracted or reflected by the refraction-reflection layer, and as a result, the light is emitted in a concentrated manner, thereby improving the efficiency of light emission from a front surface of the OLED display device.

### BRIEF DESCRIPTION OF DRAWINGS

In order to more clearly illustrate the embodiments of the present disclosure or related art, figures which will be described in the embodiments are briefly introduced hereinafter. It is obvious that the drawings are merely for the purposes of illustrating some embodiments of the present disclosure, and a person having ordinary skill in this field can obtain other figures according to these figures without an inventive work.

FIG. 1 is a schematic structural view illustrating an organic light-emitting diode (OLED) display device according to one embodiment of the present invention;

FIG. 2 is a schematic structural view illustrating the OLED display device according to another embodiment of the present invention;

FIG. 3 is a schematic structural view illustrating the OLED display device according to still another embodiment of the present invention; and

FIG. 4 is a schematic structural view illustrating the OLED display device according to yet another embodiment of the present invention.

### DETAILED DESCRIPTION OF EMBODIMENTS

The following descriptions are provided with reference to specific embodiments of the present invention. The directional terms mentioned in the present invention, such as “upper”, “lower”, “front”, “rear”, “left”, “right”, “inside”, “outside”, and “lateral” are for ease of understanding of the present invention based on the accompanying drawings, but not for limiting the present invention. In the drawings, structurally similar units are denoted by the same reference numerals.

The drawings and description are illustrative rather than restrictive. In the drawings, structurally similar units are denoted by the same reference numerals. In addition, for ease of understanding and description, the size and thickness of each component shown in the drawings are illustrative, and the present invention is not limited thereto.

In the drawings, thicknesses of layers, films, panels, regions, and etc. are exaggerated for clarity. In the drawings, the thicknesses of some layers and regions are exaggerated for the convenience of understanding and description. It should be noted that when a component such as a layer, a film, a region, or a substrate is referred to as being “on” another component. The component may be directly on the other component, or there may be an intermediate component between them.

In addition, in the specification, unless otherwise explicitly described, the word “comprising” is construed as including the said component, but not excluding other components. In addition, in the specification, “on” means to be above or below the component, and does not necessarily mean to be on top of the component in the direction of gravity.

In order to further explain the technical means and effects of the present invention, the following specifically describes an organic light-emitting diode (OLED) display device and a display device of the present invention with reference to the accompanying drawings and preferable embodiments.

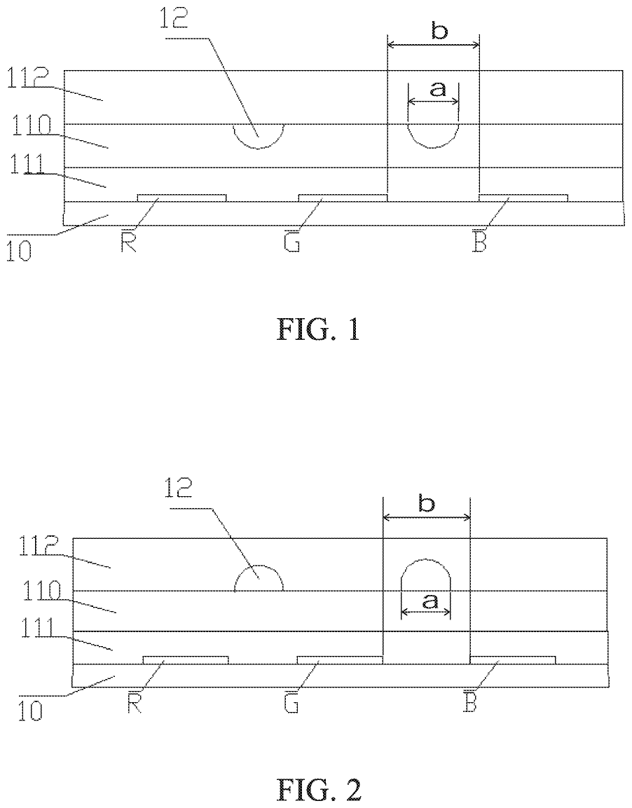

Referring to FIG. 1, it is a schematic structural view illustrating an OLED display device according to one embodiment of the present invention. The OLED display device comprises a light-emitting layer 10, an encapsulation layer 11, and a refraction-reflection layer 12 inside the encapsulation layer 11. The refraction-reflection layer 12 is used to refract or reflect light emitted from the light-emitting layer, so that the light can be emitted concentratedly.

In the present invention, by adding a refraction-reflection layer into an encapsulation layer of the OLED display device, the refraction-reflection layer can change a path of light emitted to the surroundings, so that light emitted from a light-emitting layer of the OLED display device is refracted or reflected by the refraction-reflection layer. As a result, the light is emitted in a concentrated manner, thereby improving efficiency of light emission from a front side of the OLED display device.

Although the OLED display device is described with the above structure, some necessary conventional structures have not been described in detail. In addition to the above structure, the OLED display device of the present invention can also include any other necessary structures as required. For example, in the embodiment of the present invention, the OLED display device further includes a flexible substrate, a thin film transistor (TFT) layer disposed on the flexible substrate, and a pixel definition layer 13 disposed on the TFT layer. The pixel definition layer 13 comprises a plurality of red, green, and blue (R, G, and B) pixels, and the R, G, and B pixel units are spaced apart from each other. There is a certain distance b between each two adjacent pixels. In other words, an opening distance between each two adjacent pixels is the distance b.

In the embodiment of the present invention, the encapsulation layer 11 is used to encapsulate the OLED display device. The encapsulation layer 11 comprises a first organic layer 110, a first inorganic layer 111, a second inorganic layer 112. The first inorganic layer 111 is disposed under the refraction-reflection layer 12. The second inorganic layer 112 is disposed above the refraction-reflection layer 12. The first organic layer 110 is disposed between the first inorganic layer 111 and the second inorganic layer 112.

The first inorganic layer 111 is disposed on the light-emitting layer 10 for protecting the light-emitting layer 10. The first organic layer 110 is disposed above the first inorganic layer 111, and a plurality of grooves are defined in the first organic layer 110. The refraction-reflection layer 12 is invertedly disposed in the grooves of the first organic layer 110.

According to one embodiment of the present invention, a refractive index n1 of the refraction-reflection layer 12 is greater than a refractive index n2 of the first organic layer 110.

A refractive index n3 of the second inorganic layer 112 is greater than or equal to the refractive index n1 of the refraction-reflection layer 12. To be specific, the refractive index n3 of the second inorganic layer 112 is greater than the refractive index n1 of the refraction-reflection layer 12; or alternatively, the refractive index n3 of the second inorganic layer 112 is equal to the refractive index n1 of the refraction-reflection layer 12.

In the OLED display device of the present invention, when the light-emitting layer 10 emits light, a portion of the light is directly emitted, and a portion of the light reaches a boundary between the first organic layer 110 and the refraction-reflection layer 12. Because the refractive index n1 of the refraction-reflection layer 12 is greater than the refractive index n2 of the first organic layer 110, the light is refracted after entering the refraction-reflection layer 12, and the light is deflected and radiated toward the center, so that the light can be emitted concentratedly, thereby increasing a light output ratio.

Further, if the refractive index n3 of the second inorganic layer 112 is greater than the refractive index n1 of the refraction-reflection layer 12, when the light reaches the boundary between the refraction-reflection layer 12 and the second inorganic layer 112, the light is refracted after entering the second inorganic layer 112 because the refractive index n3 of the second inorganic layer 112 is greater than the refractive index n1 of the refraction-reflection layer 12. As a result, the light is deflected toward the center, so that the light can be emitted concentratedly, thereby increasing the light output ratio of the OLED display device.

If the refractive index n3 of the second inorganic layer 112 is equal to the refractive index n1 of the refraction-reflection layer 12, the light is not refracted but directly emitted when it reaches the boundary between the refraction-reflection layer 12 and the second inorganic layer 112. However, the light is already refracted compared with a direction of the light entering the refraction-reflection layer 12, so the light is emitted in a concentrated manner. Compared with conventional techniques, the light output ratio of the OLED display device is increased.

According to one embodiment of the present invention, a light transmittance of the refraction-reflection layer is greater than 90%.

In the OLED display device of the above embodiment, the refraction-reflection layer 12 can include a plurality of refraction-reflection portions, and the refraction-reflection portions are spaced apart from each other. A cross section of the refraction-reflection portion is oval or circular.

Moreover, a plurality of arc-shaped grooves are defined in one side of the first organic layer 110 away from the first inorganic layer 111, and the arc-shaped grooves are oval or circular. The refraction-reflection portions are invertedly disposed in the organic layer, and the refraction-reflection portions are disposed corresponding to the grooves, respectively.

According to one embodiment of the present invention, a width a of the refraction-reflection portion is less than or equal to an opening distance b between each two adjacent pixels.

To be specific, the width a of the refraction-reflection portion is less than the opening distance b between each two adjacent pixels in the OLED display device; or alternatively, the width a of the refraction-reflection portion is equal to the opening distance b between each two adjacent pixels in the OLED display device. The refraction-reflection portion is disposed above an opening between each two adjacent pixels in the pixel definition layer 13.

In other embodiments, the refraction-reflection layer 12 can be disposed above the first organic layer 110, as shown in FIG. 2. FIG. 2 is a schematic structural view illustrating the OLED display device according to another embodiment of the present invention.

In the present embodiment, the refractive index n1 of the refraction-reflection layer 12 is greater than the refractive index n2 of the first organic layer 110.

Furthermore, the refractive index n3 of the second inorganic layer 112 is greater than or equal to the refractive index n1 of the refraction-reflection layer 12. To be specific, the refractive index n3 of the second inorganic layer 112 is greater than the refractive index n1 of the refraction-reflection layer 12; or alternatively, the refractive index n3 of the second inorganic layer 112 is equal to the refractive index n1 of the refraction-reflection layer 12.

In the OLED display device according to one embodiment of the present invention, when the light-emitting layer 10 emits light, a portion of the light is directly emitted, and a portion of the light reaches the boundary between the first organic layer 110 and the refraction-reflection layer 12. Because the refractive index n1 of the refraction-reflection layer 12 is greater than the refractive index n2 of the first organic layer 110, the light is refracted after entering the refraction-reflection layer 12, and the light is deflected toward the center, so that the light can be emitted concentratedly, thereby increasing the light output ratio.

Further, if the refractive index n3 of the second inorganic layer 112 is greater than the refractive index n1 of the refraction-reflection layer 12, when the light reaches the boundary between the refraction-reflection layer 12 and the second inorganic layer 112, the light is refracted after entering the second inorganic layer 112, the light is deflected toward the center, so that the light is emitted concentratedly, thereby increasing the light output ratio of the OLED display device.

If the refractive index n3 of the second inorganic layer 112 is equal to the refractive index n1 of the refraction-reflection layer 12, the light is not refracted but directly emitted when it reaches the boundary between the refraction-reflection layer 12 and the second inorganic layer 112. However, the light is already refracted compared with a direction of the light entering the refraction-reflection layer 12, and consequently, the light is emitted in a concentrated manner. Compared with the conventional techniques, the light output ratio of the OLED display device is increased.

According to one embodiment of the present invention, a light transmittance of the refraction-reflection layer 12 is greater than 90%.

In the OLED display device of the above embodiment, the refraction-reflection layer 12 can include a plurality of refraction-reflection portions, and the refraction-reflection portions are spaced apart from each other. A cross section of the refraction-reflection portion is oval or circular.

The refraction-reflection portions are disposed above the first organic layer 110, and the oval or circular cross-sections of the refraction-reflection layer 12 are disposed away from the first organic layer 110.

In the above embodiment of the present invention, a width a of the refraction-reflection portion is less than or equal to an opening distance b between each two adjacent pixels.

To be specific, the width a of the refraction-reflection portion is less than the opening distance b between each two adjacent pixels in the OLED display device; or alternatively, the width a of the refraction-reflection portion is equal to the opening distance b between each two adjacent pixels in the OLED display device. The refraction-reflection portion is disposed above an opening between each two adjacent pixels in the pixel definition layer 13.

In the OLED display device of the above embodiment, the refraction-reflection layer 12 is made of an organic material, and the organic material can be a commonly used insulating material. An insulating structure made of this material has the advantages of a uniform film thickness and a small refractive index error. The refraction-reflection layer can be made by pressing.

According to one embodiment of the present invention, the refraction-reflection layer and the organic layer can be made of a same material, or can be made of different materials.

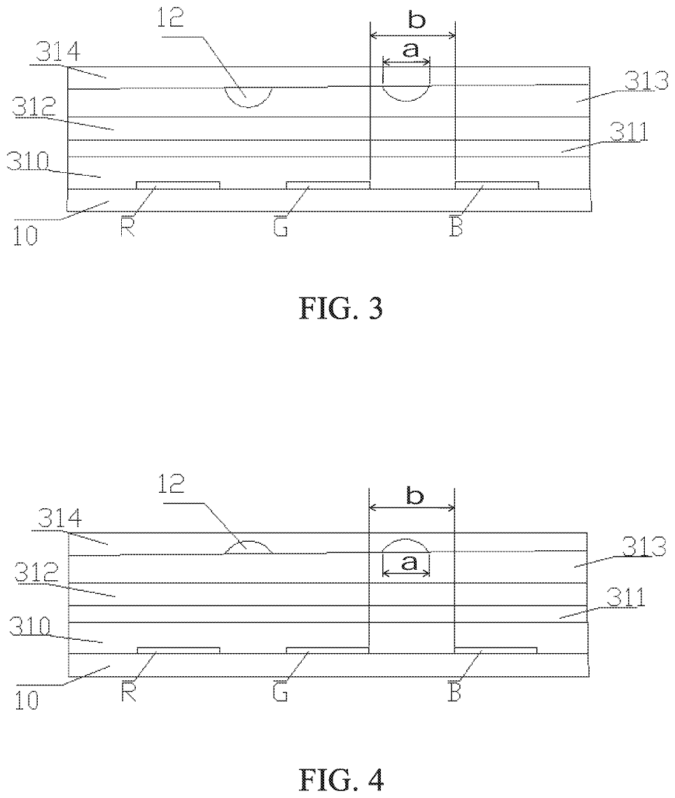

Referring to FIG. 3, it is a schematic structural view of the OLED display device according to another embodiment of the present invention. The encapsulation layer 11 of the OLED display device includes a first inorganic layer 310, a first organic layer 311, and a second inorganic layer 312, a second organic layer 313, and a third inorganic layer 314. In the OLED display device, the encapsulation layer 11 is disposed on the light-emitting layer 10 and arranged in the order of the first inorganic layer 310, the first organic layer 311, the second inorganic layer 312, the second organic layer 313, and the third inorganic layer 314.

In some embodiments of the present invention, a refraction-reflection layer 12 is disposed in the second organic layer 313, as shown in FIG. 3, which is a schematic view of the OLED display device according to a third embodiment of the present invention. A plurality of grooves are defined in the second organic layer 313. The refraction-reflection layer 12 is invertedly disposed in the grooves of the second organic layer 313.

According to one embodiment of the present invention, a refractive index n1 of the refraction-reflection layer 12 is greater than a refractive index n4 of the second organic layer 313.

Furthermore, a refractive index n5 of the third inorganic layer 314 is greater than or equal to the refractive index n1 of the refraction-reflection layer 12. To be specific, the refractive index n5 of the third inorganic layer 314 is greater than the refractive index n1 of the refraction-reflection layer 12; or alternatively, the refractive index n5 of the third inorganic layer 314 is equal to the refractive index n1 of the refraction-reflection layer 12.

In the OLED display device of the above embodiment of the present invention, when the light-emitting layer 10 emits light, a portion of the light is directly emitted, and a portion of the light reaches the boundary between the second organic layer 313 and the refraction-reflection layer 12. Because the refractive index n1 of the refraction-reflection layer 12 is greater than the refractive index n4 of the second organic layer 313, the light is refracted after entering the refraction-reflection layer 12, and the light is deflected toward the center, so that the light can be emitted concentratedly, thereby increasing the light output ratio.

Furthermore, if the refractive index n5 of the third inorganic layer 112 is greater than the refractive index n1 of the refraction-reflection layer 12, when the light reaches the boundary between the refraction-reflection layer 12 and the third inorganic layer 314, the light is refracted after entering the third inorganic layer 112 because the refractive index n5 of the third inorganic layer 112 is greater than the refractive index n1 of the refraction-reflection layer 12. Consequently, the light is deflected toward the center, so that the light is emitted concentratedly, thereby increasing the light output ratio of the OLED display device.

If the refractive index n5 of the third inorganic layer 314 is equal to the refractive index n1 of the refraction-reflection layer 12, the light is not refracted but directly emitted when it reaches the boundary between the refraction-reflection layer 12 and the third inorganic layer 314. However, the light is already refracted compared with a direction of the light entering the refraction-reflection layer 12, and consequently, the light is emitted in a concentrated manner. Compared with the conventional techniques, the light output ratio of the OLED display device is increased.

According to one embodiment of the present invention, a light transmittance of the refraction-reflection layer 12 is greater than 90%.

In the OLED display device of the above embodiment, the refraction-reflection layer 12 can include a plurality of refraction-reflection portions, and the refraction-reflection portions are spaced apart from each other. A cross section of the refraction-reflection portion is oval or circular.

A plurality of grooves are defined in the second organic layer 313, and the grooves are oval or circular. The refraction-reflection portions are invertedly disposed in the second organic layer 313, and the refraction-reflection portions are disposed corresponding to the grooves, respectively.

According to one embodiment of the present invention, a width a of the refraction-reflection portion is less than or equal to an opening distance b between each two adjacent pixels in the OLED display device.

To be specific, the width a of the refraction-reflection portion is less than the opening distance b between each two adjacent pixels in the OLED display device; or alternatively, the width a of the refraction-reflection portion is equal to the opening distance b between each two adjacent pixels in the OLED display device.

The refraction-reflection layer 12 is disposed above an opening between each two adjacent pixels in a pixel definition layer 13.

In other embodiments of the present invention, the refraction-reflection layer 12 is disposed above the second organic layer 313, as shown in FIG. 4, which is a schematic view of the OLED display device according to another embodiment of the present invention.

According to the present embodiment of the present invention, a refractive index n1 of the refraction-reflection layer 12 is greater than a refractive index n4 of the second organic layer 313.

Furthermore, a refractive index n5 of the third inorganic layer 314 is greater than or equal to the refractive index n1 of the refraction-reflection layer 12. To be specific, the refractive index n5 of the third inorganic layer 314 is greater than the refractive index n1 of the refraction-reflection layer 12; or alternatively, the refractive index n5 of the third inorganic layer 314 is equal to the refractive index n1 of the refraction-reflection layer 12.

In the OLED display device of the above embodiment of the present invention, when the light-emitting layer 10 emits light, a portion of the light is directly emitted, and a portion of the light reaches the boundary between the second organic layer 313 and the refraction-reflection layer 12. Because the refractive index n1 of the refraction-reflection layer 12 is greater than the refractive index n4 of the second organic layer 313, the light is refracted after entering the refraction-reflection layer 12, and the light is deflected toward the center, so that the light can be emitted concentratedly, thereby increasing the light output ratio of the OLED display device.

Furthermore, if the refractive index n5 of the third inorganic layer 313 is greater than the refractive index n1 of the refraction-reflection layer 12, when the light reaches the boundary between the refraction-reflection layer 12 and the third inorganic layer 314, the light is refracted after entering the third inorganic layer 314 because the refractive index n5 of the third inorganic layer 313 is greater than the refractive index n1 of the refraction-reflection layer 12. Consequently, the light is deflected toward the center, so that the light is emitted concentratedly, thereby increasing the light output ratio of the OLED display device.

If the refractive index n5 of the third inorganic layer 314 is equal to the refractive index n1 of the refraction-reflection layer 12, the light is not refracted but directly emitted when it reaches the boundary between the refraction-reflection layer 12 and the third inorganic layer 314. However, the light is already refracted compared with a direction of the light entering the refraction-reflection layer 12, and consequently, the light is emitted in a concentrated manner. Compared with the conventional techniques, the light output ratio of the OLED display device is increased.

According to one embodiment of the present invention, a light transmittance of the refraction-reflection layer 12 is greater than 90%.

In the OLED display device of the above embodiment, the refraction-reflection layer 12 can include a plurality of refraction-reflection portions, and the refraction-reflection portions are spaced apart from each other. A cross section of the refraction-reflection layer 12 is oval or circular.

The refraction-reflection portions are disposed above the second organic layer 313, and the oval or circular cross-sections of the refraction-reflection layer 12 are disposed away from the second organic layer 313.

In the OLED display device of the above embodiment, the refraction-reflection layer 12 is made of an organic material, and the organic material can be a commonly used insulating material. An insulating structure made of this material has advantages of a uniform film thickness and a small refractive index error. The refraction-reflection layer can be made by pressing.

According to one embodiment of the present invention, the refraction-reflection layer 12 and the second organic layer 313 can be made of a same material or different materials.

According to one embodiment of the present invention, the width a of the refraction-reflection portion is less than or equal to the opening distance b between each two adjacent pixels in the OLED display device. The refraction-reflection portion is disposed above the opening between each two adjacent pixels in the pixel definition layer 13.

The present invention further provides a display apparatus. The display device includes the OLED display By adding a refraction-reflection layer into an encapsulation layer of the OLED display device, the refraction-reflection layer can change a path of light emitted to the surroundings, so that the light emitted from the light-emitting layer of the OLED display device is refracted or reflected by the refraction-reflection layer, and as a result, the light is emitted in a concentrated manner, thereby improving the efficiency of light emission from a front surface of the OLED display device.

According to the above objectives of the present invention, a display apparatus is provided. The display apparatus includes the above-mentioned OLED display device. Working principles of the display apparatus provided in the present embodiment are consistent with the working principles of the OLED display device of the foregoing embodiments. For specific structural relationship and working principles, please refer to the OLED display device of the foregoing embodiments, so details are not described herein again.

In summary, although the present invention has been disclosed as above with preferable embodiments, the above preferable embodiments are not intended to limit the present invention. Those skilled in the art can make various modifications without departing from the spirit and scope of the present invention. Therefore, the protection scope of the present invention is defined by the appended claims of the present invention.

What is claimed is:

1. An organic light-emitting diode (OLED) display device, comprising a light-emitting layer, an encapsulation layer, and a refraction-reflection layer disposed in the encapsulation layer, wherein the refraction-reflection layer is configured to refract or reflect light of the light-emitting layer, so that the light is emitted concentratedly.

2. The OLED display device according to claim 1, wherein the encapsulation layer comprises a first inorganic layer, a second inorganic layer, and an organic layer disposed between the first inorganic layer and the second inorganic layer; the first inorganic layer is disposed on the light-emitting layer, the refraction-reflection layer is disposed on the organic layer, and the second inorganic layer is disposed on the refraction-reflection layer.

3. The OLED display device according to claim 2, wherein a refractive index of the refraction-reflection layer is greater than a refractive index of the organic layer.

4. The OLED display device according to claim 2, wherein a refractive index of the second inorganic layer is greater than or equal to a refractive index of the refraction-reflection layer.

5. The OLED display device according to claim 2, wherein the refraction-reflection layer comprises a plurality of refraction-reflection portions, and the refraction-reflection portions are spaced apart from each other.

6. The OLED display device according to claim 5, wherein a plurality of arc-shaped grooves are defined in one side of the organic layer away from the first inorganic layer, the refraction-reflection portions are correspondingly disposed in the arc-shaped grooves, and a cross-section of each refraction-reflection portion is oval or circular.

7. The OLED display device according to claim 5, wherein the OLED display device further comprises a flexible substrate, a thin film transistor (TFT) layer disposed on the flexible substrate, and a pixel definition layer disposed on the TFT layer; the pixel definition layer comprises a plurality of pixels spaced apart from each other, and a width of the refraction-reflection portion is less than or equal to an opening distance between each two adjacent pixels.

8. The OLED display device according to claim 7, wherein the refraction-reflection portion is disposed above an opening between each two adjacent pixels.

9. The OLED display device according to claim 1, a light transmittance of the refraction-reflection layer is greater than 90%.

10. The OLED display device according to claim 1, wherein the refraction-reflection layer and the organic layer are made of a same material.

11. A display apparatus, wherein the display apparatus comprises an organic light-emitting diode (OLED) display device, the OLED display device comprises a light-emitting layer, an encapsulation layer, and a refraction-reflection layer disposed in the encapsulation layer, and the refraction-reflection layer is used to refract or reflect light emitted from the light-emitting layer, so that the light is emitted concentratedly.

12. The display apparatus according to claim 11, wherein the encapsulation layer comprises a first inorganic layer, a second inorganic layer, and an organic layer disposed between the first inorganic layer and the second inorganic layer, the first inorganic layer is disposed on the light-emitting layer, the refraction-reflection layer is disposed on the organic layer, and the second inorganic layer is disposed on the refraction-reflection layer.

13. The display apparatus according to claim 12, wherein a refractive index of the refraction-reflection layer is greater than a refractive index of the organic layer.

14. The display apparatus according to claim 12, wherein a refractive index of the second inorganic layer is greater than or equal to a refractive index of the refraction-reflection layer.

15. The display apparatus according to claim 12, wherein the refraction-reflection layer comprises a plurality of refraction-reflection portions, and the refraction-reflection portions are spaced apart from each other.

16. The display apparatus according to claim 15, wherein a plurality of arc-shaped grooves are defined in one side of the organic layer away from the first inorganic layer, the refraction-reflection portions are correspondingly disposed in the arc-shaped grooves, and a cross-section of each refraction-reflection portion is oval or circular.

17. The display apparatus according to claim 15, wherein the OLED display device further comprises a flexible substrate, a thin film transistor (TFT) layer disposed on the flexible substrate, and a pixel definition layer disposed on the TFT layer; the pixel definition layer comprises a plurality of pixels spaced apart from each other, and a width of the refraction-reflection portion is less than or equal to an opening distance between each two adjacent pixels.

18. The display apparatus according to claim 17, wherein the refraction-reflection portion is disposed above an opening between each two adjacent pixels.

19. The display apparatus according to claim 11, a light transmittance of the refraction-reflection layer is greater than 90%.

20. The display apparatus according to claim 11, wherein the refraction-reflection layer and the organic layer are made of a same material.
